(19) United States
(12) Patent Application Publication
(10) Pub. No.: US 2026/0161873 A1
(43) Pub. Date: Jun. 11, 2026

(54) SCAN MODE FOR AN ASYNCHRON COUNTER

(71) Applicant: Renesas Design Austria GmbH, Graz (AT)

(72) Inventor: Michael PIEBER, Graz (AT)

(73) Assignee: Renesas Design Austria GmbH, Graz (AT)

(21) Appl. No.: 18/969,697

(22) Filed: Dec. 5, 2024

(51) Int. Cl. G06F 30/333

(52) U.S. Cl. CPC G06F 30/333

(57) ABSTRACT

An integrated circuit for processing of data in a functional mode and for testing of the integrated circuit in a scan mode is provided. The integrated circuit includes a processing unit, a digital functional block, an asynchronous counter, an asynchronous counter test stage, a comparator. The processing unit is built to process and store data in the functional mode of the integrated circuit based on a system clock. The digital functional block is realized with registers and a number of N scan flip flops with each of the scan flip flops connected to the system clock. The asynchronous counter is realized with a number of M flip flops connected in a chain. The asynchronous counter test stage is built to reset the count data and store test data in the digital functional block to prepare the testing of the asynchronous counter in a scan mode of the asynchronous counter.

### FIELD

The present invention relates to an integrated circuit for processing of data in a functional mode and for testing of the integrated circuit in a scan mode.

### BACKGROUND

Known integrated circuits for processing of data are for instance integrated circuits for Radio Frequency IDentification communication systems used in RFID readers or transmitters to communicate with active or passive receivers. In a typical application, a passive receiver (e.g. transponder or tag) stores object identification information of an object to which it is attached and the transmitter (e.g. reader) is used to obtain this object information. The transmitter is powered and generates a magnetic RF-Field emitted by its antenna. When the transmitter and the tag are within close proximity of each other, the transmitter generated RF-Field is induced into the antenna of the tag and used to power the passive tag. The tag also has a transceiver to receive the signal from the reader and to transmit a response back to the transmitter as load modulated receiver data signal. Apart from this example, the invention may be used in any kind of integrated circuits outside of the RFID technology area as well.

Such known integrated circuits comprise digital functional blocks like for instance shift registers that may be used as synchronous counters to process data in the integrated circuit. FIG. 1 shows a scan flip flop 1 with a flip flop 2 according to the state of the art. Flip flop 2 comprises an input 3 for data bits and a clock input 4 to connect it to a system clock CLK of the integrated circuit and a direct flip flop output 5 to provide output data Q and only optional an inverted flip flop output 6 to provide inverted output data Q̅. A multiplexer 7 is added at the input 3 of the flip flop 2 with one data input 8 of the multiplexer 7 acting as the functional input for the data D in a functional mode of the scan flip flop 1. A scan input 9 of the multiplexer 7 is used in a scan mode of the scan flip flop 1 to receive scan data SI. Multiplexer 7 is switched by a scan enable signal SE at a scan enable input SEI to either provide the data D at data input 3 of the flip flop 2 in the functional mode to process the data D or to provide the scan data SI to data input 3 of the flip flop 2 in the scan mode.

FIG. 2 shows a functional register 10 similar to a shift register according to the state of the art, which is built by three such scan flip flops 1 connected in a chain. It is named functional register 10, because it is connected to a combinatorial logic block 12 as explained below. Data input 8 of first scan flop flop 1 of the chain receives the data D from other hardware of the integrated circuit like for instance a central processing unit or a finite state machine. The direct flip flop output 5 of the last scan flip flop 1 in the chain provides output data Q of the functional register 10 in the functional mode of the functional register 10. Scan input 9 of first scan flop flop 1 of the chain receives the scan data SI and all multiplexer 7 of the flip flops 2 in the chain are connected with their scan enable inputs SEI to the scan enable signal SE, which is active in the scan mode. All flip flops 2 of the chain are connected to the system clock CLK and with each pulse 11 of the system clock CLK, shown in FIG. 3, bits “0” or “1” of either data D or scan data SI are shifted from one of the flip flops 1 to the next flip flop 1 in the chain, as it is the function of the functional register 10 in the functional mode.

Scan testing of the functional register 10 is done in order to detect any manufacturing fault in a combinatorial logic block 12 shown in FIG. 2, which symbolizes the logic hardware processing software of the integrated circuit connected to the functional register 10. Hardware of the integrated circuit may be tested and software may be debugged, step by step. Scan testing of the functional register 10 is furthermore done to detect hardware faults in the functional register 10 as well. The scan mode of the functional register 10 is activated by the central processing unit of the integrated circuit or by a signal input at a pin of the integrated circuit, whereupon a shift register test stage processes a scan operation, which involves three stages: Scan-in, Scan-capture and Scan-out. Scan-in involves shifting in and loading all the scan flip-flops 1 of the functional register 10 with an input vector in the form of the scan data SI. During scan-in, the bits of the scan data SI flow from the output of one scan flip flop 1 to the scan input 9 of the next scan flip flop 1. Once the sequence of bits of the scan data SI is loaded, one pulse 11 of system clock CLK, also called the capture pulse CP, is allowed to excite the combinatorial logic block 12 in the scan-capture stage. The output of the combinatorial logic block 12 is captured in the scan flip flops 1 of the functional register 10. The captured data is then shifted out in the scan-out stage of the scan mode and the signature of these bits is compared with the expected signature of a correct functioning integrated circuit. Shift register test stages can use the captured sequence as the next input vector for the next shift-in cycle. Moreover, in case of any mismatch, they can point to the nodes where one can possibly find any manufacturing fault. FIG. 3 shows the above explained sequence of events that take place during scan mode of functional register 10.

With above described shift register test stage and scan mode it is possible to test the correct function of shift registers and synchronous counters realized with shift registers, but it is not possible to test asynchronous counters. Asynchronous counters are for instance used in a standby mode of the integrated circuit to minimize current consumption of the clock-tree, by waking-up the integrated circuit after the asynchronous counter counted to a special count value that corresponds to the duration of the standby mode, just to give one example. FIG. 4 shows an example of an asynchronous counter 13 with five flip flops 2 connected in a chain in a special way to enable the functionality of the asynchronous counter 13. Data input 8 and inverted flip flop output 6 of flip flops 2 in the chain are connected to the clock input 4 of the next flip flop 2 in the chain. Direct flip flop outputs 5 form an output data bus 14 with the counter value CNT of the asynchronous counter 13. The first flip flop 2 in the chain is connected with its clock input 4 to a test clock CCLK, which may be the system clock CLK of the integrated circuit or a clock signal with a different clock frequency. Each flip flop 2 is connected with a reset input 15 to a reset signal RST which is used to reset the counter value CNT stored in the asynchronous counter 13. With this special connections of the flip flops 2, asynchronous counter 13 is built to count-up with each pulse 11 of test clock CCLK. A scan mode for asynchronous counter 13 is not possible with a scan mode as described above for the functional register 10, because the flop flops 2 are not connected to a common system clock CLK and it is not possible in a scan-in stage to shift scan data SI into the flip flops 2 of the asynchronous counter 13, as the asynchronous counter 13 just counts up. Therefore, in state of the art integrated circuits, it is only possible to either not test the asynchronous counters, what increases risk to deliver defect integrated circuits, or to add special test hardware onto the chip that is only needed in test the asynchronous counter and increases the chip area and complexity of the integrated circuit.

### SUMMARY

It is an object of the invention to provide an integrated circuit with an asynchronous counter, which enables a test of the asynchronous counter in a scan mode. This object is achieved with an integrated circuit as claimed in claim 1.

The inventive asynchronous counter test stage together with its comparator to compare the test data stored in the shift register with the count data stored in the asynchronous counter at the scan capture time enables to test the functionality of the asynchronous counter in scan mode. It is possible to test its functionality without adding substantial additional test hardware to the integrated circuit what keeps the chip area small and does not increase the complexity of the integrated circuit. Furthermore, the functionality of the asynchronous counter is tested with the anyhow in the integrated circuit available shift register, as both the shift register and the asynchronous counter are needed in the functional mode of the integrated circuit. Therefore the asynchronous counter may be tested parallel to and/or at the same time with the scan mode test of the shift register, what saves test time and reduces the manufacturing costs of the integrated circuit. Special test patterns for test data to test the functionality of the asynchronous counter in the scan mode are used in a preferred embodiment of the invention. It is furthermore advantageous to fix the test data at a value close to the maximum count value of the asynchronous counter, because if the asynchronous counter counted correct until this high count value all count values below will have been correct as well.

These and other aspects of the invention will be apparent from and elucidated with reference to the embodiments described hereinafter. The person skilled in the art will understand that various embodiments may be combined.

### BRIEF DESCRIPTION OF THE DRAWINGS

FIG. 1 shows a scan flip flop according to the state of the art.

FIG. 2 shows a functional register according to the state of the art with three scan flip flops of FIG. 1.

FIG. 3 shows shows the sequence of events that take place during scan mode of the functional register of FIG. 2.

FIG. 4 shows an asynchronous counter according to the state of the art with five flip flops of FIG. 1.

FIG. 5 shows a synchronous counter and an asynchronous counter of an integrated circuit according to the invention.

FIG. 6 shows the sequence of events that take place during scan mode of the asynchronous counter of FIG. 5.

### DETAILED DESCRIPTION OF EMBODIMENTS

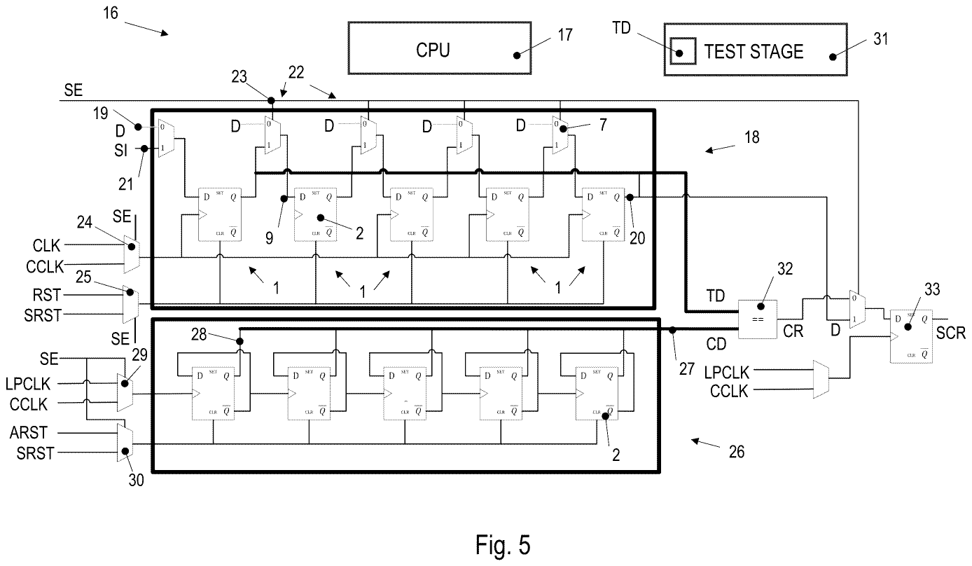

FIG. 5 shows an integrated circuit 16 for processing of data D in a functional mode of the integrated circuit 16 and for testing of the integrated circuit 16 in a scan mode of the integrated circuit 16. The functional mode is the mode where the integrated circuit 16 realizes those functions that it is built for and why it is implemented in a product. For example the integrated circuit 16 could be a reader IC for an RFID reader that realizes the function to enable RFID wireless communication via an antenna connected to the reader IC and that furthermore realizes the function to process data D received via the wireless communication from another device. But the invention is not limited to this RFID technology area and could be used in any other technology area as well. Integrated circuit 16 comprises a central processing unit 17 built to process and store data D in a memory in the functional mode of the integrated circuit 16 based on a system clock CLK. Integrated circuit 16 comprises all kind of other hardware elements needed to realize its function, but FIG. 5 shows only those elements relevant to the invention.

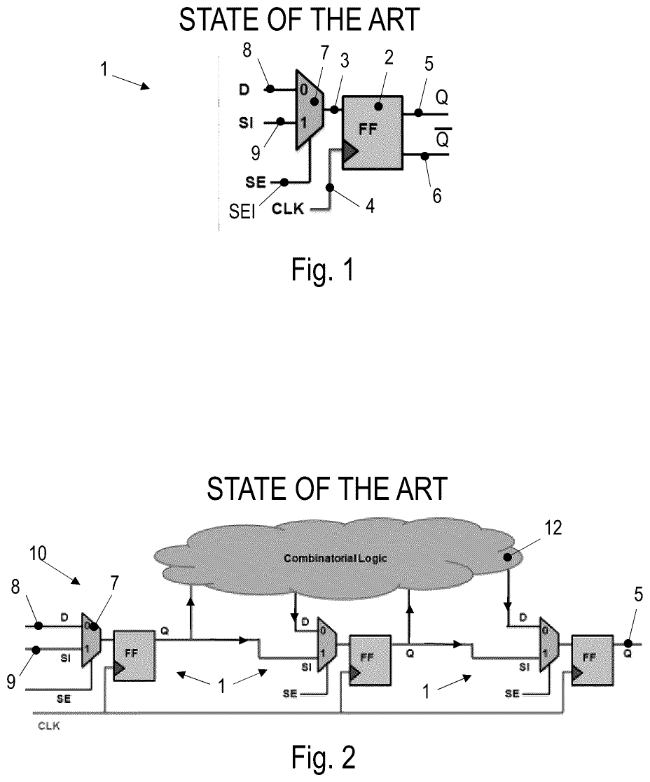

Integrated circuit 16 furthermore comprises a digital functional block 18 realized with a number of N=5 scan flip flops 1, which in the scan mode is arranged as shift register as shown in FIG. 1. In the functional mode digital functional block may function as any kind of registers like special function register to store bits. The scan flip flops 1 are connected in a chain with each of the scan flip flops 1 connected to the system clock CLK as shown in FIG. 2 and explained above. Digital functional block 18 is built to process data D of the integrated circuit 16 in the functional mode and is built to be tested for correct functionality in the scan mode of the digital functional block 18 as explained above for the shift register 10. In the embodiment shown in FIG. 5 digital functional block 18 in its functional mode realizes a synchronous counter.

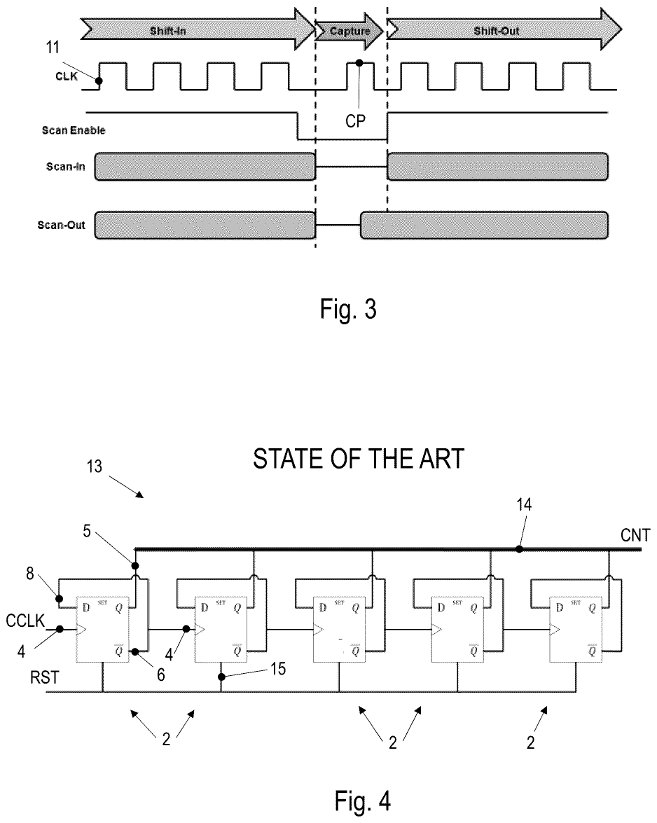

A data input 19 of first scan flop flop 1 in the chain receives the data D from the central processing unit 17 or other hardware of the integrated circuit 16. A direct flip flop output 20 of the last scan flip flop 1 in the chain provides as output of the digital functional block 18 a serial stream of data bits of data Q in the functional mode of the digital functional block 18. Scan input 21 of the first scan flop flop 1 in the chain receives scan data SI that are used in the scan mode to test the correct functionality of the digital functional block 18. All multiplexer 22 of the scan flip flops 1 in the chain are connected with their scan enable inputs 23 to the scan enable signal SE, which is active in the scan mode. All scan flip flops 1 in the chain are connected to the system clock CLK and with each pulse 11 of the system clock CLK, shown in FIG. 3, bits “0” or “1” of either data D or scan data SI are shifted from one of the flip flops 1 to the next flip flop 1 in the chain, as it is the function of the digital functional block 18 in the functional mode. A multiplexer 24 is used to switch with the scan enable signal SE between the system clock CLK for the functional mode and a test clock CCLK for the scan mode of an asynchronous counter 26 of the integrated circuit 16. Test clock CCLK is generated and controlled by a tester which usually is an external testing machine connected via pins of the integrated circuit 16 and comprises a lower frequency as system clock CLK what enables to use the same from external of the integrated circuit 16 controllable test clock CCLK as for the scan of the digital functional block 18. In other embodiments the test clock CCLK comprises a higher frequency as the system clock CLK. Furthermore, a multiplexer 25 is used to switch with the scan enable signal SE between a reset signal RST for the functional mode and a scan reset signal SRST for the scan mode of the integrated circuit 16. These two different reset signals for digital functional block 18 in the two different modes enable to control the reset of the scan mode from the external testing machine.

Integrated circuit 16 furthermore comprises the asynchronous counter 26 realized with a number of M=5 flip flops 2 connected in a chain, which asynchronous counter 26 is built to provide count data CD based on the test clock CCLK in the functional mode of the integrated circuit 17. This asynchronous counter 26 therefore may count-up the count data CD from a value of “0 ” up to a maximal value of the count data CD of “32” or may count-down the count data CD from a value of “32” up to a minimal value of the count data CD of “0”. Count data CD are provided on a data bus 27, which has the number of M=5 data lines, each connected to one of the direct flip flop outputs 28. A multiplexer 29 is used to switch with the scan enable signal SE between a low power clock LPCLK for the functional mode and the test clock CCLK for the scan mode of the integrated circuit 16. Low power clock LPCLK comprises a lower frequency as test clock CCLK what enables to reduce power consumption. Furthermore, a multiplexer 30 is used to switch with the scan enable signal SE between an asynchron reset signal ARST for the functional mode and the scan reset signal SRST for the scan mode of the integrated circuit 16. These two different reset signals for digital functional block 18 in the two different modes enable to control the reset of the integrated circuit 16 in scan mode from the external testing machine.

Integrated circuit 16 furthermore comprises an asynchronous counter test stage 31 built to reset the count data CD and built to store test data TD in the digital functional block 18 to prepare the testing of the asynchronous counter 26 in the scan mode of the asynchronous counter 26. Asynchronous counter test stage 31 is a stack of software processed by the central processing unit 17 or any other hardware within the integrated circuit 16 and memory space linked to it, wherein the test data TD are stored. In other embodiments asynchronous counter test stage 31 could be an external tester connected via pins of integrated circuit 16 and could be realized in hardware only. Test data TD is a special number or value of the count data CD for which the asynchronous counter 26 has to be tested in the scan mode. So in principle the test data TD could be any value between “1” up to the maximal value of the count data CD of “32” in this embodiment. This is of course a very simple example as the asynchronous counter 26 may comprise a high number of flip flops 2 and count data CD of “16.384” or even much higher are possible in other embodiments of the invention.

It is advantageous to define the test data TD in the upper range closer to the maximal value of the count data CD, because if the test in the scan mode results in the fact that the asynchronous counter 26 counted correct until that high count data CD, then there is a high chance that all count data CD below this value have to be correct counted as well. In a preferred embodiment the test data TD are defined as the maximal value of the count data CD divided by two plus 1. This ensures that all flip flops 2 are tested. To avoid that two errors based on hardware defects of the asynchronous counter 26 result in the correct high count data CD, if they compensate each other, but lead to wrong count data CD in the range of lower count data CD, different test data TD may be stored to process more tests in the full range of the possible count data CD. The result of the test of the asynchronous counter 26 with different test data TD enables to provide a clear location of the hardware error in the asynchronous counter 26 for all kind of different errors.

In different embodiments flip flops 2 of the asynchronous counter 26 may be structured in several blocks each with several flip flops 2 and it is advantageous that the asynchronous counter test stage 31 is built to store different test patterns of test data TD to test the functionality of a single block of the asynchronous counter 26 in the scan mode. This enables to provide a clear location of the hardware error in the asynchronous counter 26.

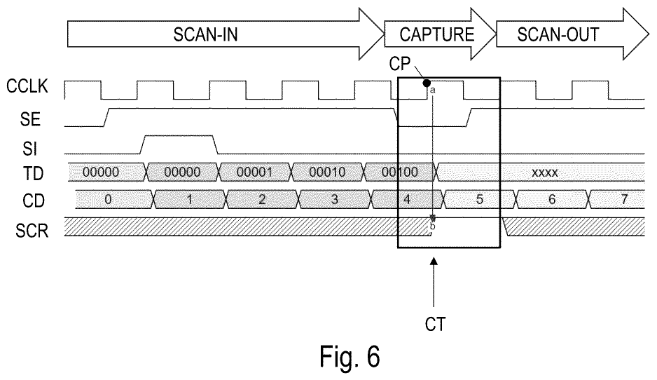

Integrated circuit 16 furthermore comprises a comparator 32 built to compare the test data TD, stored in the digital functional block 18, with the count data CD, stored in the asynchronous counter 26, at a scan capture time CT of the scan mode, when a number of C clock cycles of the test clock CCLK were processed after the reset of the count data CD. Comparator 32 outputs compare result CR. FIG. 6 shows the sequence of events that take place during a scan mode of the asynchronous counter 26. This scan mode for the asynchronous counter 26 has three stages: Scan-in, Scan-capture and Scan-out. Scan-in involves shifting in and loading all the scan flip-flops 1 of the digital functional block 18 with an input vector in the form of the scan data SI. In the scan mode of the asynchronous counter 26 the scan data SI are the test data TD stored in the asynchronous counter test stage 31. During scan-in, the bits of the test data TD flow from the direct flip flop output of one scan flip flop 1 to the scan input 9 of the next scan flip flop 1. Once the sequence of bits of the test data TD is loaded, one pulse of test clock CCLK, also called the capture pulse CP, is used to store the compare result CR from the comparator 32, that compares the test data TD with the actual count data CD, in a test result flip flop 33. During scan-out, integrated circuit 16 is built to rotate the stored compare result SCR stored in the test result flip flop 33 out. If the asynchronous counter 26 after the C clock cycles of the test clock CCLK counted correct and therefore counted-up to the same value of the counter data CD as stored in the test data TD, comparator 32 provides a bit (“0” or “1”) that indicates that both input data busses comprised the same value. If on the other hand one or more flip flops 2 of the asynchronous counter 26 comprised a hardware defect, then the counter data CD and the test data TD at capture time CT will have different values what will be indicated by the comparator 32 and stored in the result flip flop 33 which unequal case can be executed as well in case the test data TD is deliberately different from the count data CD.

A big advantage of the inventive scan mode for asynchronous counter 26 is that no extra hardware is needed and that the asynchronous counter 26 is tested with hardware used in functional mode as well. This avoids the case where the asynchronous counter 26 would work correct, but extra the hardware for testing has a problem. This avoidance of extra hardware for the scan mode for asynchronous counter 26 furthermore saves area on the integrated circuit 16.

In the example shown in FIG. 6, test data TD are the bits “00100” what is the binary code for the count data CD=“4”. This means with the sequence of events shown in FIG. 6 that take place during scan mode of the asynchronous counter 26 it is tested, if the asynchronous counter 26 counts correct from count data CD=“0” to count data CD=“4”. In the embodiment shown in FIG. 5, the five scan flip flops 1 of shrift register 18 and the five flip flops 2 of asynchronous counter 26 are only first blocks and the digital functional block 18 and the asynchronous counter 26 may have several of these blocks. In a preferred embodiment, the result flip flop 33 is one of the flip flops 2 of the scan flip flops 1 of a block of the digital functional block 18 and the asynchronous counter test stage 31 is built to shift out the result of the test in a scan-out stage of the scan mode of the asynchronous counter 26. This enables to test the asynchronous counter 26 without any additional hardware needed in the integrated circuit 16 and just done by the test of the digital functional block 18.

The asynchronous counter test stage 31 is built to let the test clock CCLK count-up the count data CD to a value of the test data TD to be tested at the scan capture time CT minus the number of counts realized while the number of N scan flip flops 1 of the digital functional block 18 is filled with the test data TD. In another embodiment the asynchronous counter test stage 31 is built to let the test clock CCLK count-down the count data CD to a value of the test data TD to be tested at the scan capture time CT plus the number of counts realized while the number of N scan flip flops 1 of the digital functional block 18 is filled with the test data TD. This enables to save test time as the digital functional block 18 is filled with test data TD at least partially parallel to and at the same time the asynchronous counter 26 counts up the last counts until the count data CD to be tested.

With above described embodiment of the invention shown in FIG. 5 and FIG. 6 a method for testing of the integrated circuit 16 in a scan mode of the asynchronous counter 26 is disclosed. This method comprises the following steps:
Reset the count data CD of the asynchronous counter 26 after the scan mode has been activated;
Let the asynchronous counter 26 count-up or count-down the count data CD to a value of the test data TD to be tested at the scan capture time CT minus the number of counts realized while the number of N scan flip flops 1 of the digital functional block 18 is filled with the test data TD;
Load the digital functional block 18 with the test data TD while the asynchronous counter 26 counts-up or counts-down the count data CD to the value of the test data TD to be tested at the scan capture time CT;
Compare the test data TD with the count data CD at the scan capture time CT and store the result of the comparison as a result of the test of the asynchronous counter 26 in the scan mode.

In above explained embodiment the count data CD were reset and the number of C cycles of the test clock were processed from this reset count data CD. This reset is not needed every time in scan mode as the knowledge of a starting value of the count data CD is good enough to count up or down the number of C cycles of the count data. The starting value may be any value from zero to the maximal value of the count data CD.

In another embodiment of the invention the system clock CLK is used as test clock CCKL as well.

In another embodiment of the invention the processing unit is realized as finite state machine. Furthermore the processing unit may be realized in hardware only as ASIC or as a hardware processing unit that processes a stack of software.

A digital functional block may for instance realize a shift register or a special function register or a counter or any other block to store or manipulate bits, like an FSM or CPU.

1. An integrated circuit for processing of data in a functional mode and for testing of the integrated circuit in a scan mode, the integrated circuit comprising:
a processing unit built to process and store data in the functional mode of the integrated circuit based on a system clock;
a digital functional block realized with a number of N scan flip flops with each of the scan flip flops connected to the system clock, which digital functional block is built to process data in the functional mode and is built to be tested for correct functionality in the scan mode, wherein in scan mode the number of N scan flip flops are connected in a chain;
an asynchronous counter realized with a number of M flip flops connected in a chain, which asynchronous counter is built to provide count data based on a low power clock in the functional mode of the integrated circuit;
an asynchronous counter test stage built to reset the count data and built to store test data in the digital functional block to prepare the testing of the asynchronous counter in a scan mode of the asynchronous counter;
a comparator built to compare the test data stored in the digital functional block with the count data stored in the asynchronous counter at a scan capture time of the scan mode of the asynchronous counter, when a number of C cycles of a test clock were processed after the reset of the count data or with the knowledge of a starting value of the counter data, and wherein a comparator output of this comparison is stored in a test result flip flop as result of the test of the asynchronous counter in the scan mode.

2. The integrated circuit according to claim 1, wherein the test result flip flop is one of the flip flops of the digital functional block and wherein the asynchronous counter test stage is built to shift out the result of the test in a scan-out stage of the scan mode.

3. The integrated circuit according to claim 1, wherein the asynchronous counter test stage is built to let the test clock trigger to count-up or count-down the count data to a value of the test data to be tested at the scan capture time minus or plus the number of counts realized while the number of N scan flip flops of the digital functional block is filled with the test data.

4. The integrated circuit according to claim 1, wherein the asynchronous counter test stage is built to fix the test data at a value of the maximum count value of the asynchronous counter divided by two plus one.

5. The integrated circuit according to claim 1, wherein the asynchronous counter is built with at least two separate blocks that each at least comprise two flip flops and wherein the asynchronous counter test stage is built to store different test patterns for test data to test the functionality of a single block of the asynchronous counter in the scan mode.

6. The integrated circuit according to claim 1, wherein the system clock has a higher clock frequency as the test clock.

7. The integrated circuit according to claim 1, wherein the integrated circuit is connected to an antenna and a tuning circuit and is built to receive an antenna signal with the carrier frequency of the system defined NFC resonance frequency of 13.56 MHz.

8. A method for testing of an integrated circuit according to claim 1 in a scan mode of the asynchronous counter, the method comprising:
resetting the count data of the asynchronous counter after the scan mode has been activated;
allowing the asynchronous counter count-up the count data to a value of the test data to be tested at the scan capture time minus the number of counts realized while the number of N scan flip flops of the digital functional block is filled with the test data;
loading the registers of the digital functional block with the test data; and
comparing the test data with the count data at the scan capture time and store the result of the comparison as a result of the test of the asynchronous counter in the scan mode.
